(19) United States
(12) Patent Application Publication
(10) Pub. No.: US 2014/0102768 A1
(43) Pub. Date: Apr. 17, 2014

(54) WIRING BOARD AND METHOD FOR MANUFACTURING THE SAME

(71) Applicant: IBIDEN CO., LTD., Ogaki-shi (JP)

(72) Inventors: Yoshinori SHIZUNO, Ogaki-shi (JP); Makoto Terui, Ogaki-shi (JP); Masatoshi Kunieda, Ogaki-shi (JP); Takashi Kariya, Ogaki-shi (JP)

(73) Assignee: IBIDEN CO., LTD., Ogaki-shi (JP)

(21) Appl. No.: 14/053,854

(22) Filed: Oct. 15, 2013

(30) Foreign Application Priority Data
Oct. 16, 2012 (JP) 2012-229295

(51) Int. Cl. H05K 1/02; H05K 3/46

(52) U.S. Cl. CPC H05K 1/0298; H05K 3/4644
USPC 174/251; 427/97.3

(57) ABSTRACT

A wiring board includes a first insulation layer, a first conductive pattern structure formed on the first insulation layer, a wiring structure formed on the first insulation layer and including a second insulation layer and a second conductive pattern structure on the second insulation layer, and a third insulation layer formed on the first insulation layer and the first conductive pattern structure and having first and second openings such that the first opening is exposing at least a portion of a surface of the wiring structure and the second opening is exposing at least a portion of the first conductive pattern structure. The wiring structure includes a third conductive pattern structure forming an outermost layer of the wiring structure and including a mounting pad structure which mounts a semiconductor device. The first opening is formed such that the first opening is exposing pad formation area of the mounting pad structure.

### CROSS-REFERENCE TO RELATED APPLICATIONS

The present application is based upon and claims the benefit of priority to Japanese Patent Application No. 2012-229295, filed Oct. 16, 2012, the entire contents of which are incorporated herein by reference.

### BACKGROUND OF THE INVENTION

1. Field of the Invention

The present invention relates to a wiring board and a method for manufacturing the same; more specifically, to a wiring board having a partial region of high wiring density and a method for manufacturing the same.

2. Description of Background Art

In recent years, IC chips are miniaturized and highly integrated, thus increasing the number of pads formed on the uppermost layer of a package substrate. As the number of pads increases, a pitch of the pad (40 to 50 μm) is also narrowed. Such a narrow pitch also makes a wiring pitch of the package substrate narrower (for example, refer to WO 2007/129454 A).

High density wiring may be formed in a region that is part of such a wiring board. Specifically, inside an interlayer insulation layer of a wiring board, an electronic component having such a high density wiring layer is arranged on a substrate that is made of a heat-resistant base material such as silicon or glass and has a low thermal expansion coefficient. The entire contents of this publication are incorporated herein by reference.

### SUMMARY OF THE INVENTION

According to one aspect of the present invention, a wiring board includes a first insulation layer, a first conductive pattern structure formed on the first insulation layer, a wiring structure formed on the first insulation layer and including a second insulation layer and a second conductive pattern structure on the second insulation layer, and a third insulation layer formed on the first insulation layer and the first conductive pattern structure and having a first opening portion and a second opening portion such that the first opening portion is exposing at least a portion of a surface of the wiring structure and the second opening portion is exposing at least a portion of the first conductive pattern structure. The wiring structure includes a third conductive pattern structure forming an outermost layer of the wiring structure and including a mounting pad structure formed to mount a semiconductor device, and the first opening portion is formed such that the first opening portion is exposing a pad formation area of the mounting pad structure.

According to another aspect of the present invention, a method of manufacturing a wiring board includes forming a first conductive pattern structure on a first insulation layer, positioning on the first insulation layer a wiring structure including a second insulation layer, a second conductive pattern structure on the second insulation layer and a third conductive pattern structure forming an outermost layer of the wiring structure, forming on the first insulation layer a third insulation layer such that the third insulation layer covers the wiring structure and the first conductive pattern structure, forming a first opening portion in the third insulation layer such that the first opening portion exposes at least a portion of the third conductive pattern structure of the wiring structure, and forming a second opening portion in the third insulation layer such that the second opening portion exposes at least a portion of the first conductive pattern structure. The third conductive pattern structure includes a pad formation area for mounting a semiconductor device, and the forming of the first opening includes exposing the pad formation area of the third conductive pattern structure.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view illustrating a package substrate obtained by applying a wiring board according to a first embodiment of the invention (the lower half is an enlarged cross-sectional view of a region “A” illustrating main parts of the upper half);

FIG. 1B is a detailed cross-sectional view illustrating the package substrate obtained by applying the wiring board according to the first embodiment of the invention;

FIG. 2 is a plan view of FIG. 1A as seen from a (Z2) direction;

FIG. 3 is a diagram illustrating main parts of the wiring board according to the first embodiment by enlarging a part of FIG. 1A (the lower half is an enlarged cross-sectional view of a region “B” illustrating main parts of the upper half);

FIG. 4 is a flowchart illustrating a process of manufacturing a wiring structure according to the first embodiment;

FIG. 5A is a cross-sectional process diagram illustrating a method for manufacturing the wiring structure of FIG. 4;

FIG. 5B is a cross-sectional process diagram illustrating a method for manufacturing the wiring structure of FIG. 4;

FIG. 5C is a cross-sectional process diagram illustrating a method for manufacturing the wiring structure of FIG. 4;

FIG. 5D is a cross-sectional process diagram illustrating a method for manufacturing the wiring structure of FIG. 4;

FIG. 5E is a cross-sectional process diagram illustrating a method for manufacturing the wiring structure of FIG. 4;

FIG. 5F is a cross-sectional process diagram illustrating a method for manufacturing the wiring structure of FIG. 4;

FIG. 5G is a cross-sectional process diagram illustrating a method for manufacturing the wiring structure of FIG. 4;

FIG. 5H is a cross-sectional process diagram illustrating a method for manufacturing the wiring structure of FIG. 4;

FIG. 5I is a cross-sectional process diagram illustrating a method for manufacturing the wiring structure of FIG. 4;

FIG. 6 is a flowchart illustrating a process of manufacturing the wiring board according to the first embodiment;

FIG. 7A is a cross-sectional process diagram illustrating a method for manufacturing the wiring board of FIG. 6;

FIG. 7B is a cross-sectional process diagram illustrating a method for manufacturing the wiring board of FIG. 6;

FIG. 7C is a cross-sectional process diagram illustrating a method for manufacturing the wiring board of FIG. 6;

FIG. 7D is a cross-sectional process diagram illustrating a method for manufacturing the wiring board of FIG. 6;

FIG. 7E is a cross-sectional process diagram illustrating a method for manufacturing the wiring board of FIG. 6;

FIG. 7F is a cross-sectional process diagram illustrating a method for manufacturing the wiring board of FIG. 6;

FIG. 7G is a cross-sectional process diagram illustrating a method for manufacturing the wiring board of FIG. 6;

FIG. 7H is a cross-sectional process diagram illustrating a method for manufacturing the wiring board of FIG. 6;

FIG. 7I is a cross-sectional process diagram illustrating a method for manufacturing the wiring board of FIG. 6 (the lower half is an enlarged cross-sectional view of a region “C” illustrating main parts of the upper half);

FIG. 7J is a cross-sectional process diagram illustrating a method for manufacturing the wiring board of FIG. 6;

FIG. 7K is a cross-sectional process diagram illustrating a method for manufacturing the wiring board of FIG. 6;

FIG. 7L is a cross-sectional process diagram illustrating a method for manufacturing the wiring board of FIG. 6;

FIG. 7M is a cross-sectional process diagram illustrating a method for manufacturing the wiring board of FIG. 6;

FIG. 7N is a cross-sectional process diagram illustrating a method for manufacturing the wiring board of FIG. 6;

FIG. 8 is a plan view illustrating main parts of a wiring board according to a first modified example of the first embodiment;

FIG. 9 is a cross-sectional view illustrating main parts of a wiring board according to a second modified example of the first embodiment (the lower half is an enlarged cross-sectional view of a region “C” illustrating main parts of an upper diagram); and

FIG. 10 is a cross-sectional view illustrating a package substrate obtained by applying a wiring board according to a second embodiment of the invention (the lower half is an enlarged cross-sectional view of a region “A” illustrating main parts of the upper half).

### DETAILED DESCRIPTION OF THE EMBODIMENTS

The embodiments will now be described with reference to the accompanying drawings, wherein like reference numerals designate corresponding or identical elements throughout the various drawings.

In the drawings, the arrows (Z1) and (Z2) indicate a laminating direction of a wiring board (or a thickness direction of a wiring board) normal to a main surface (front and rear surfaces) of each wiring board. Meanwhile, the arrows (X1), (X2), (Y1), and (Y2) indicate a direction perpendicular to the laminating direction (or a lateral side of each layer). The main surface of the wiring board lies in the (X-Y) plane and side surfaces of the wiring board lie on the (X-Z) plane or (Y-Z) plane. In the laminating direction, a side close to a core of the wiring board is referred to as a lower layer, and a side far from the core is referred to as an upper layer.

In the following embodiments, a conductive layer includes one or more conductive patterns. The conductive layer may include a conductive pattern of an electric circuit such as a wiring line (including the ground), a pad, or a land. The conductive layer may also include a planar conductive pattern without an electric circuit.

An opening includes a hole, a groove, a notch, a slit and the like.

Among the conductors formed in openings, a conductor formed in a via hole is referred to as a via conductor, a conductor formed in a through hole is referred to as a through-hole conductor, and a conductor filled in the opening is referred to as a filled conductor.

The land is a conductor formed on a hole (such as a via hole or a through hole) or in an edge thereof. At least a part of the land is integrated with the conductor inside the hole (such as a via conductor or a through-hole conductor).

A stack refers to a via conductor formed on the land of the underlying via conductor. That is, when the bottom of a via conductor is not positioned off the land of the underlying via conductor, those via conductors are stacked. Multiple via conductors stacked in this manner are referred to as stacked via conductors.

Plating includes wet plating such as electrolytic plating or electroless plating, and dry plating such as physical vapor deposition (PVD) or chemical vapor deposition (CVD).

As an interlayer material (interlayer insulation layer) or a resin material of an insulation layer of a wiring structure 10, for example, an interlayer insulating film (brand name: ABF-45SH, made by Ajinomoto) may be employed.

Unless otherwise specified, the term “width (or thickness)” of a hole or cylinder (protrusion) refers to a diameter for a circle or refers to 2√(sectional area/π) for shapes other than a circle. However, the present application is not limited to those when it is specified to use other definitions. In addition, when measurements are not uniform (for example, when the feature is uneven or tapered), an average value (average of only valid values excluding abnormal values) of measurements is employed. However, that is not the only option when it is specified that the maximum value, for example, other than the average value, is employed.

### First Embodiment

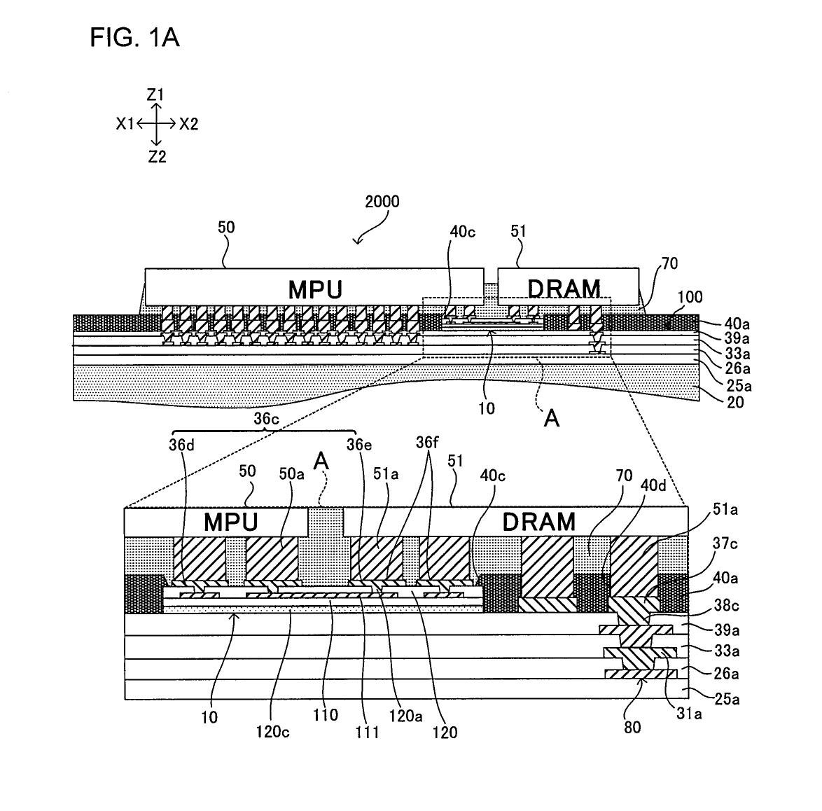

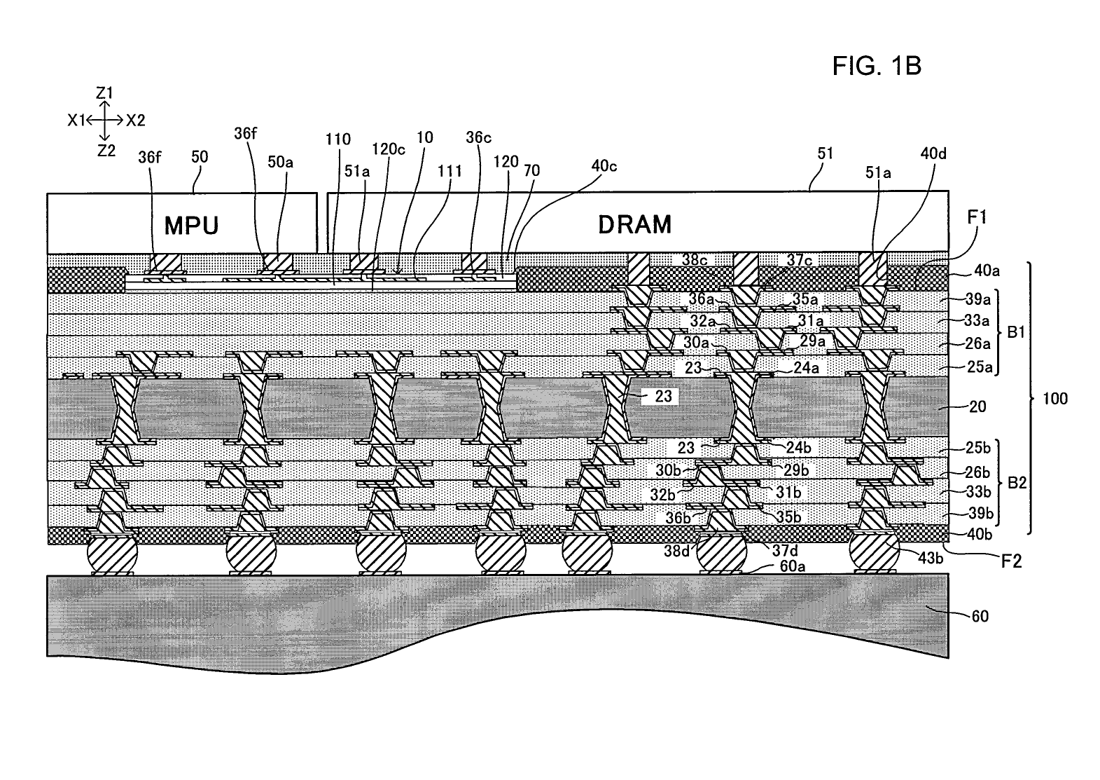

The wiring board 100 according to the embodiment is, for example, a multilayer printed wiring board illustrated in FIGS. 1A and 1B. The wiring board 100 according to the embodiment is a buildup multilayer laminated wiring board having a core substrate. However, a wiring board according to an embodiment of the present invention is not limited to such a buildup multilayer wiring board having a core substrate, and may include, for example, a double-sided rigid wiring board, a flexible wiring board, or a flex-rigid wiring board. It is noted that dimensions of the conductive layer and the insulation layer or the number of layers in the wiring board 100 may be changed within the technical scope of the present invention.

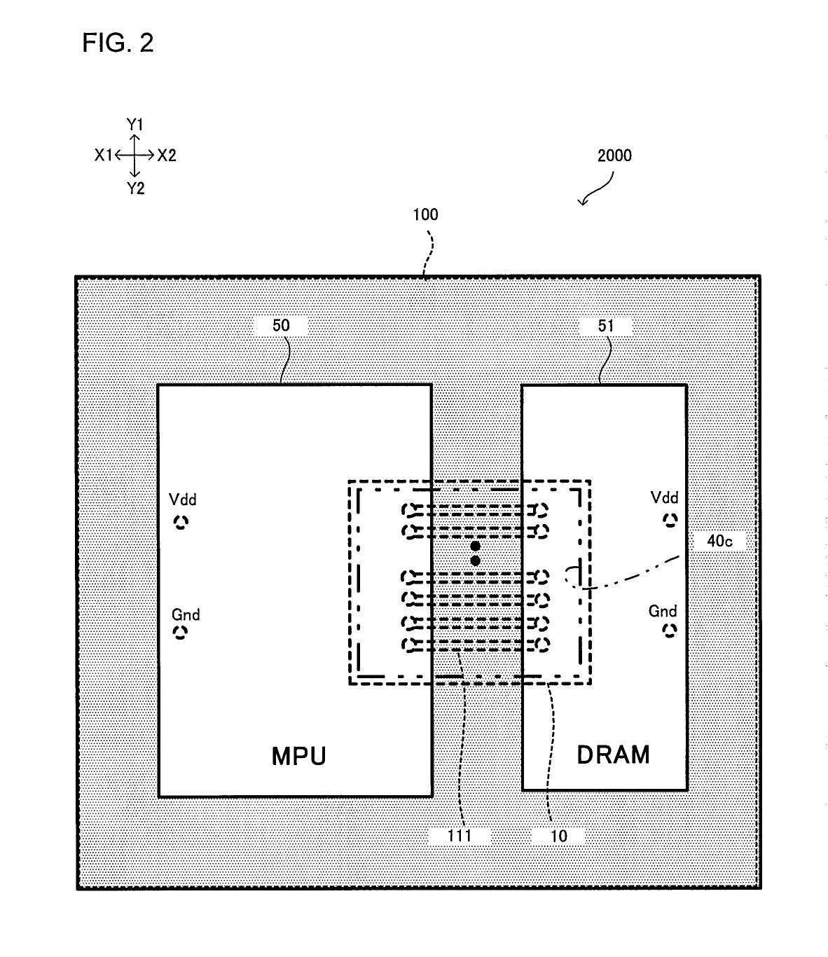

As illustrated in FIGS. 1A, 1B, and 2, a micro-processing unit (MPU) 50 as a first semiconductor device and a dynamic random access memory (DRAM) 51 as a second semiconductor device are mounted and arranged on the wiring board 100, which forms a package substrate 2000. As illustrated in FIG. 1B, the wiring board 100 is mounted and arranged on a mother board substrate 60. Gaps between the wiring board 100, the MPU 50, and the DRAM 51 are sealed with an underfill resin 70.

The wiring board 100 includes a core substrate 20, interlayer insulation layers (25a, 26a and 33a), an interlayer insulation layer (39a) (first insulation layer), interlayer insulation layers (25b, 26b, 33b and 39b), conductive layers (24a, 29a, 31a and 35a), conductive layers (37c) (first conductive pattern), (24b, 29b, 31b, 35b and 37d), via conductors (23, 30a, 32a, 36a, 38c, 30b, 32b, 36b and 38d), and solder-resist layers (40a) (third insulation layer) and (40b) formed in an outermost layer.

The wiring board 100 includes a first surface (F1) (Z1 side) and a second surface (F2) (Z2 side) opposite the first surface (F1). The via conductor 23 penetrates through the core substrate 20. The core substrate 20, the via conductor 23, and the conductive layers (24a, 24b) form a core portion. In addition, a buildup portion (B1) is formed on the first surface (a surface on the (F1) side) of the core substrate 20, and a buildup portion (B2) is formed on the second surface (a surface on the (F2) side) of the core substrate 20. The buildup portion (B1) includes four sets of the interlayer insulation layer and the conductive layer (interlayer insulation layers (25a, 26a, 33a, 39a) and conductive layers (24a, 29a, 31a, 35a, 37c)). The buildup portion (B2) includes four sets of the interlayer insulation layer and the conductive layer (interlayer insulation layers (25b, 26b, 33b, 39b) and conductive layers (24b, 29b, 31b, 35b, 37d)).

The five conductive layers (24a, 29a, 31a, 35a, 37c) and the four interlayer insulation layers (25a, 26a, 33a, 39a) are alternately laminated on the first surface of the core substrate 20 from the lower side (Z2 side). The interlayer insulation layers (25a, 26a, 33a, 39a) are formed respectively between the conductive layers (24a, 29a, 31a, 35a, 37c). In addition, a solder-resist layer (40a) is arranged on a surface of the uppermost layer of the first-surface side of the core substrate 20.

The five conductive layers (24b, 29b, 31b, 35b, 37d) and the four interlayer insulation layers (25b, 26b, 33b, 39b) are alternately laminated on the second surface of the core substrate 20. The interlayer insulation layers (25b, 26b, 33b, 39b) are formed respectively between the conductive layers (24b, 29b, 31b, 35b, 37d). In addition, a solder-resist layer (40b) is arranged on a surface of the uppermost layer of the second surface side of the core substrate 20. At least a part of the conductive layer (37c) is exposed through an opening (40d) formed on the solder-resist layer (40b).

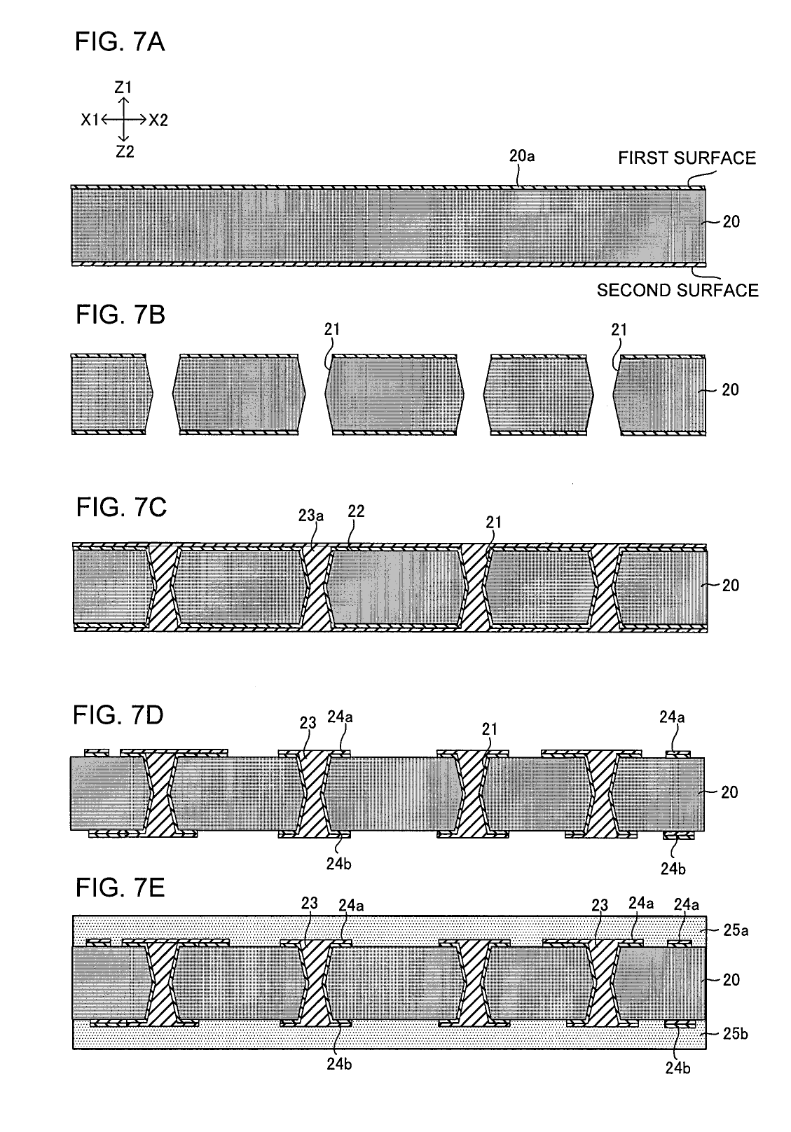

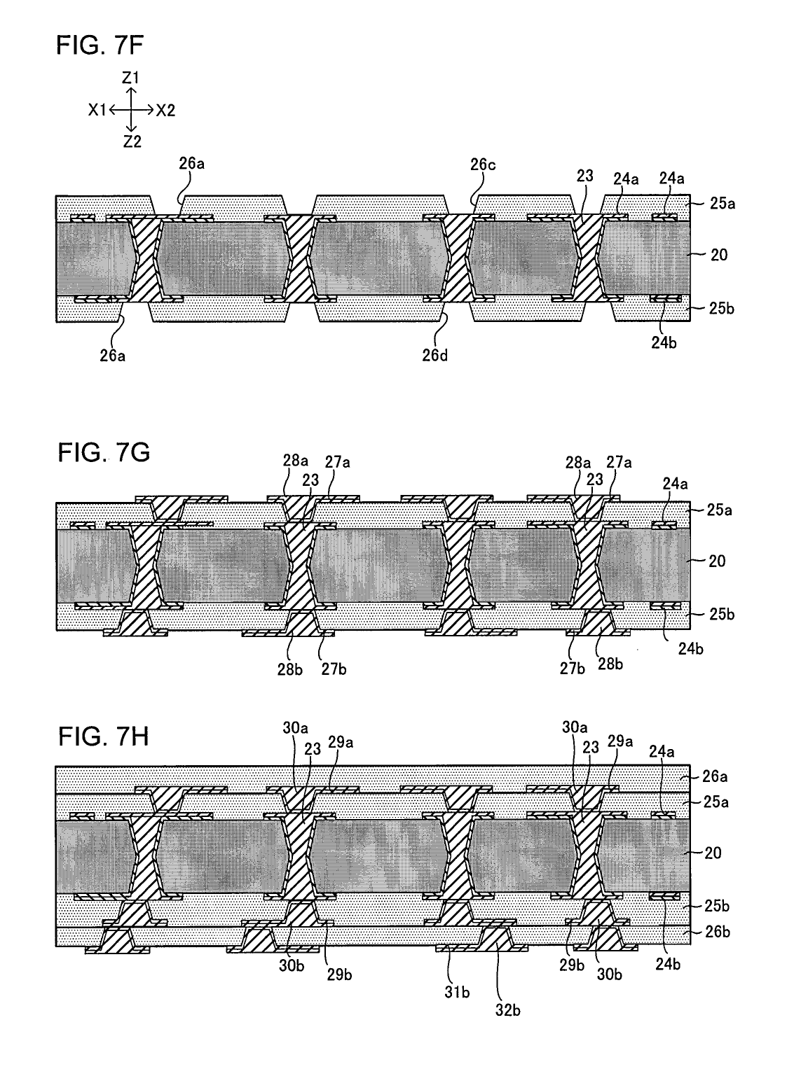

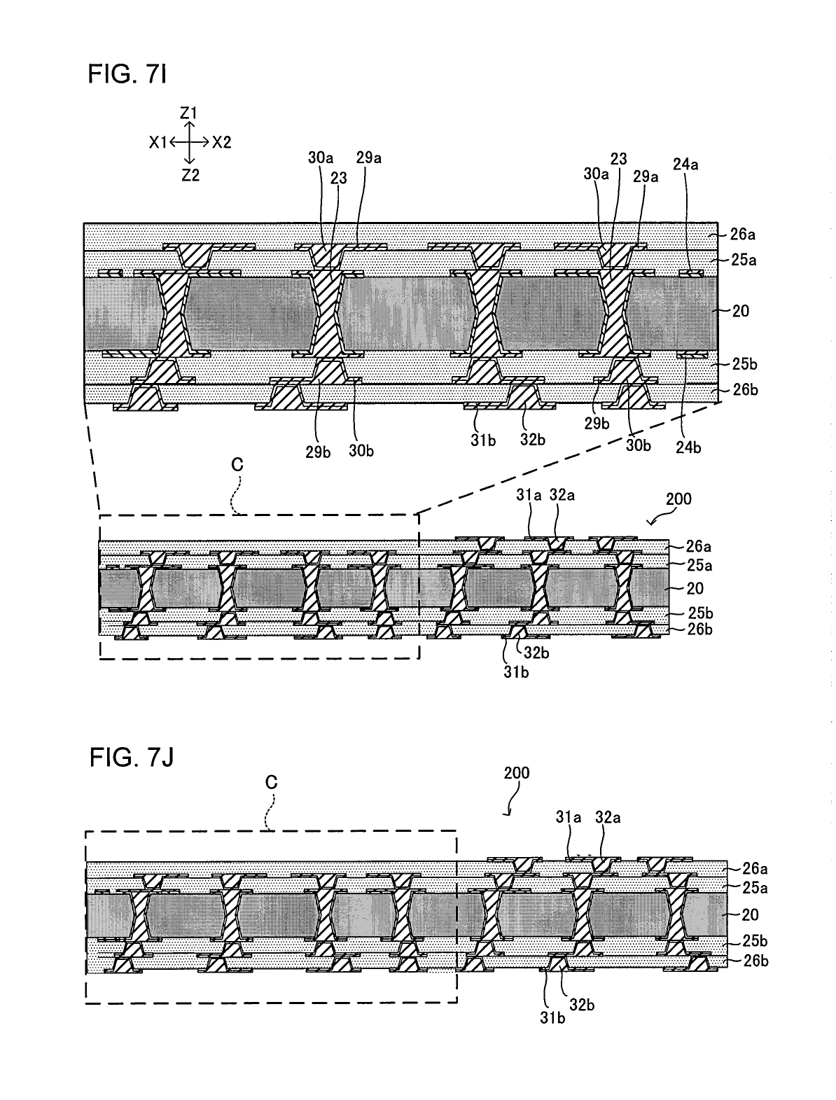

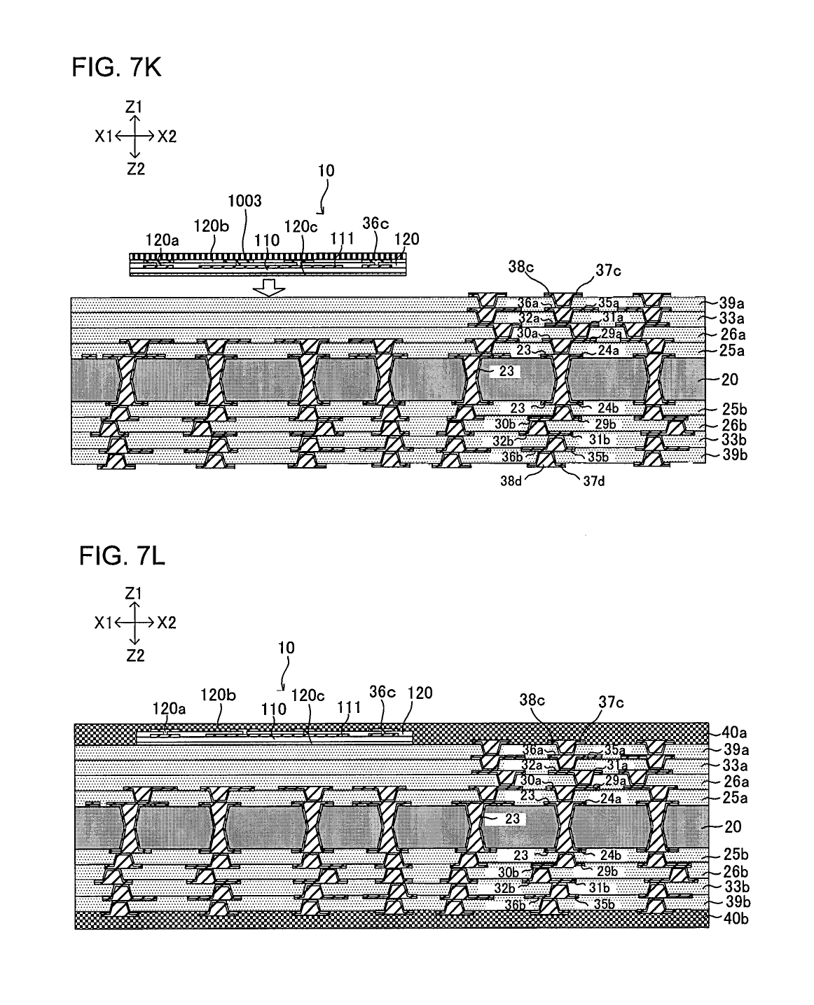

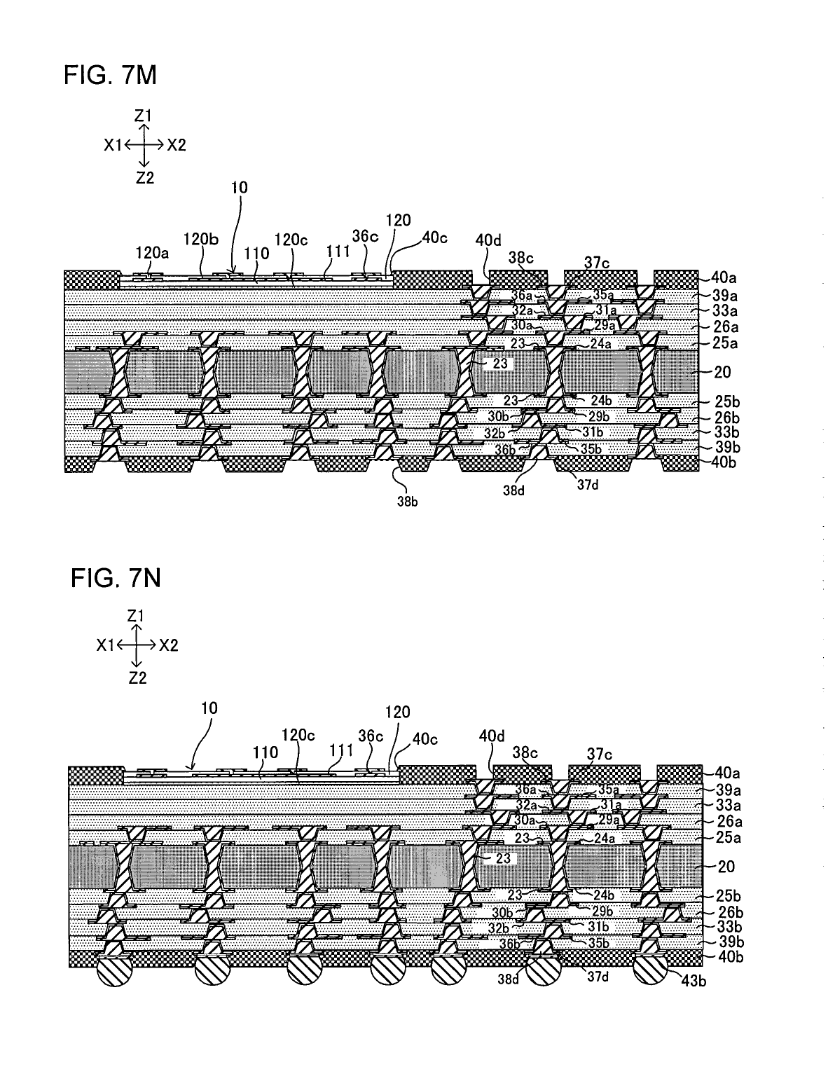

A through hole 21 (refer to FIG. 7B) penetrating through the core substrate 20 is formed in the core substrate 20. The via conductor 23 is a filled conductor formed by filling a conductor in the through hole 21. The conductive layer (24a) formed on the first-surface side of the core substrate 20 and the conductive layer (24b) formed on the second-surface side of the core substrate 20 are electrically connected to each other through the via conductor 23.

The core substrate 20 is formed by, for example, impregnating the core with resin. For example, the core substrate 20 is obtained by impregnating an epoxy resin into glass fiber fabric, thermosetting the resin, and shaping the resulting material into a plate shape. However, that is not the only option, and any other material may also be ised for the core substrate 20.

The via conductor 23 has, for example, an hourglass-like cylindrical shape whose diameter decreases toward the center from the first- and second-surface sides of the core substrate 20. In addition, a planar shape (X-Y plane) of the via conductor 23 is, for example, a perfect circle. However, the present embodiment is not limited to the above, and the via conductor 23 may have any other shape.

The via conductors (30a, 32a, 36a, 38c, 30b, 32b, 36b, 38d) are respectively formed in the interlayer insulation layers (25a, 26a, 33a, 39a, 25b, 26b, 33b, 39b). The via conductors are all filled conductors, and a conductor is filled in each via hole penetrating through each interlayer insulation layer. Each of the via conductors (30a, 32a, 36a, 38c, 30b, 32b, 36b, 38d) has, for example, a tapered cylindrical shape (truncated conical shape) whose diameter decreases toward the core substrate 20, and a planar shape (X-Y plane) that is, for example, a perfect circle. However, those are not the only options, and the via conductor (30a) or the like may have any other shape.

The interlayer insulation layer (25a) (the lowermost interlayer insulation layer of the buildup portion (B1)), the interlayer insulation layer (25b) (the lowermost interlayer insulation layers of the buildup portion (B2)), and the upper interlayer insulation layers (26a, 33a, 39a, 26b, 33b, 39b) are made of, for example, an interlayer insulating film (brand name: ABF-45SH, made by Ajinomoto). Each insulation layer is formed by, for example, impregnating a resin into the core. However, the present embodiment is not limited to the above, and any other material may be used for each insulation layer.

The wiring board 100 according to the embodiment includes a main wiring board 200 and a wiring structure 10 arranged on the main wiring board 200. The wiring structure 10 is arranged in a position in which an opening (40c) of the solder-resist layer (40a) of the main wiring board 200 is formed. A periphery (side surface) of the wiring structure 10 is covered by the solder-resist layer (40a), and the wiring structure 10 is arranged on the main wiring board 200 while an upper surface thereof is exposed through the opening (40c) (refer to FIGS. 1A, 1B, 2, and 3). In this manner, since the periphery of the wiring structure 10 is covered by the solder-resist layer (40a), a fixed state of the wiring structure 10 with respect to the interlayer insulation layer (39a) is stabilized, and connection reliability with a semiconductor device mounted on the wiring board 100 is enhanced.

A wiring line of a conductive pattern 111 of the wiring structure 10 is designed not based on a design rule of a multilayer printed wiring board, but based on a design rule of a semiconductor device such as an IC or LSI as described below. The main wiring board 200 is designed so as to have a fine line/space ratio (L/S), which is an index of the wiring density (wiring pitch). Here, the “line” refers to a pattern width, and the “space” refers to a distance between the patterns, that is, a distance between the centers of the pattern width. Specifically, the conductive pattern 111 is formed with high wiring density such that, for example, the line/space (L/S) ratio of the conductive pattern 111 is set at 1/1 μm or higher and 5/5 μm or lower, and preferably, 3/3 μm or higher and 5/5 μm or lower. This is a minute level compared with a typical multilayer printed wiring board including the main wiring board 200 according to the present embodiment having an L/S ratio of approximately 10/10 μm.

The main wiring board 200 includes a signal transmission line and a power supply line for power terminals Vdd of the MPU 50 and the DRAM 51, which are semiconductor devices (refer to FIG. 2).

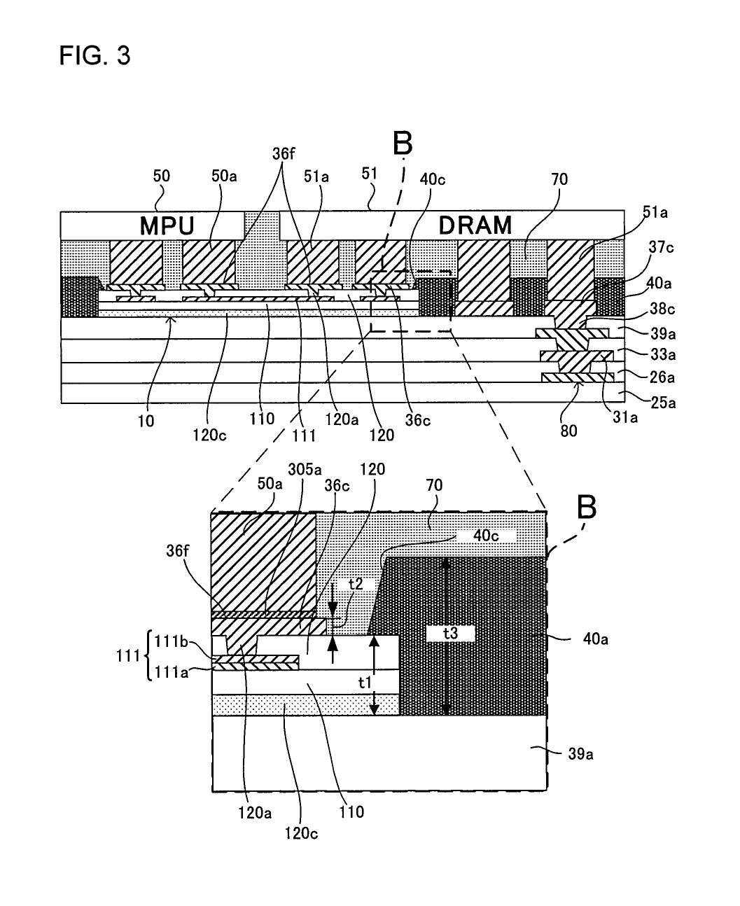

The wiring structure 10 includes an adhesive layer (120c) as a lowermost layer, an insulation layer 110 (second insulation layer) on the adhesive layer (120c), an insulation layer 120 on the insulation layer 110, and the conductive pattern 111 (second conductive pattern) for signal transmission, formed in the insulation layer 120. As illustrated in FIG. 3, the conductive pattern 111 includes first and second conductor films (111a, 111b). In the insulation layer 120, an element selected from a group of polyimide, phenol-based resin, or polybenzoxazole-based resin may be used as an insulating material. In addition, a conductor pad (36c) is formed on the wiring structure 10 in order to connect a terminal (50a) of the MPU 50 and a terminal (51a) of the DRAM 51 (refer to FIG. 3). As illustrated in FIGS. 1A, 1B, 2 and 3, the wiring structure 10 is covered by the solder-resist layer (40a) while the entire wiring structure 10 including the periphery is not exposed, but a pad formation area (36f) (pad formation surface, upper surface) where the conductor pad (36c) is formed is exposed in the opening (40c).

An adhesive used in the adhesive layer (120c) may include, for example, an epoxy resin adhesive, an acrylic resin adhesive, a silicone resin adhesive, or the like. A hole having a small diameter is formed in the insulation layer 120. A conductor is filled in this hole to form the via conductor (120a), which is a filled via.

According to the present embodiment, the wiring structure 10 includes only a signal transmission line for use in signal transmission between the MPU 50 and the DRAM 51 without a power supply line.

Specifically, the conductive pattern 111 is used for signal transmission between the MPU 50 and the DRAM 51. The power terminals Vdd of the MPU 50 and the DRAM 51 are electrically connected to a stacked via 80 (refer to FIGS. 1A and 3) in the main wiring board 200 and are supplied with power from an external DC power supply. Ground terminals Gnds (refer to FIG. 2) of the MPU 50 and the DRAM 51 are connected to the ground through another stacked via in the main wiring board 200. The wiring structure 10 is not limited to the above and may include a power supply line.

According to the present embodiment, in the uppermost layer of the main wiring board 200, the wiring structure 10 is formed such that the periphery of the wiring structure 10 is covered by the solder-resist layer (40a), and the upper surface is covered by the underfill resin 70. Accordingly, an arrangement state of the wiring structure 10 is stabilized by the solder-resist layer (40a). In addition, in the wiring structure 10, the pad formation area (360 where the conductor pad (36c) is formed is not covered by the solder-resist layer (40a), but the pad formation area (360 is exposed. For this reason, since the wiring structure 10 is less likely to be affected by a thermal history of the solder-resist layer (40a) having a different coefficient of thermal expansion (CTE), cracking is prevented in a contact portion between the wiring structure 10 and the solder-resist layer (40a). In addition, the upper surface of the wiring structure 10 is covered by the underfill resin 70. However, the underfill resin 70 has a significantly smaller CTE than that of an insulating material of the interlayer insulation layer. For this reason, stress caused by the thermal history insignificantly affects the wiring structure 10, and the cracking described above does not occur.

In addition, in such a structure, it not necessary to form a fine via hole reaching the conductor pad (36c) on the wiring structure 10 in the solder-resist layer (40a). As a result, the following effects, for example, are obtained.

It is not necessary to form a small via hole corresponding to a line having a pitch of 40 to 50 μm in the solder-resist layer (40a) serving as the insulation layer. Since forming such a small via hole in an insulation layer is difficult, eliminating the process improves the manufacturing yield of the wiring board 100.

Also, by eliminating photolithography for forming a via hole, insulation of the wiring structure 10 is not affected by a developing solution, or by eliminating a laser for forming a via hole, damage to the thin wiring structure 10 having a thickness of about 20 μm is prevented.

The via conductor (120a) is electrically connected to the conductor pad (36c). The conductor pad (36c) is electrically connected to the MPU 50 and the DRAM 51 through the terminals (50a, 51a), respectively. In addition, in the wiring board 100 according to the present embodiment, the insulation layer 110 is interposed between the conductive pattern 111 and the adhesive layer (120c). That is, the wiring structure 10 has a three-layer structure. Alternatively, without being limited to such a structure, for example, the wiring structure 10 may have a two-layer structure without the insulation layer 110, in which the conductive pattern 111 is directly formed on the adhesive layer (120c). As illustrated in FIG. 1A, in the conductor pad (36c) connected to the conductive pattern 111 of the wiring structure 10, the distance between conductor pads (36d) (first pad) connected to the MPU 50 is smaller than the distance between conductor pads (36e) (second pad) connected to the DRAM 51. In addition, the distance between the adjacent conductive patterns 111 is smaller than the distance between the adjacent conductive layers (37c).

A diameter of the via conductor (120a) is set at 1 μm or larger and 10 μm or smaller, and preferably, 0.5 μm or larger and 5 μM or smaller. Since the diameter of the via conductor (120a) is set at such a small size, the degree of freedom of wire arrangement of the conductive pattern 111 in the wiring structure 10 is improved. For example, using the conductive pattern 111 formed in only a single layer of the insulation layer 120, multiple wiring lines are extracted from one of the left and right sides of the wiring structure 10. In addition, since the conductive pattern 111 is formed in only a single layer, the total number of wiring lines in the wiring structure 10 is reduced.

As illustrated in FIG. 3, the conductor pad (36c) is connected to the terminals (50a) and (51b) through a solder (305a).

Among the dimensions of each component illustrated in FIG. 3, a thickness (t1) of a main body of the wiring structure 10 is set at 15 μm, for example, and a thickness (t2) of the conductor pad (36c) is set at 5 μm, for example. A thickness (t3) of the solder-resist layer (40a) is set at 15 μm, for example.

Although not illustrated, in the present embodiment, a surface of the conductor pad (36c) is coated with, for example, an organic solder preservative (OSP), NiPdAu, NiAu, Sn, or the like. In this manner, oxidation of the surface of the conductor pad (36c) is prevented while it is exposed to the external air.

In the present embodiment, all of the via conductors (30a, 32a, 36a, 38c, 30b, 32b, 36b, 38d) formed in the core substrate 20 have substantially the same dimensions. In such a structure, electrical characteristics, manufacturing conditions, and the like are made uniform more easily.

In the wiring board 100 according to the present embodiment, since the wiring structure 10 used for signal transmission between semiconductor devices is embedded in the main wiring board 200 with higher wiring density than that of the main wiring board 200, the degree of design freedom is increased when the wiring board 100 is formed as a multilayer printed wiring board. Situations such as, for example, the concentration of all wiring lines of a power supply system and a signal system in a specific portion of the wiring board, are prevented. Furthermore, in the area that surrounds an electronic component but does not include an electronic component, a structure having only resin without a conductor can be prevented.

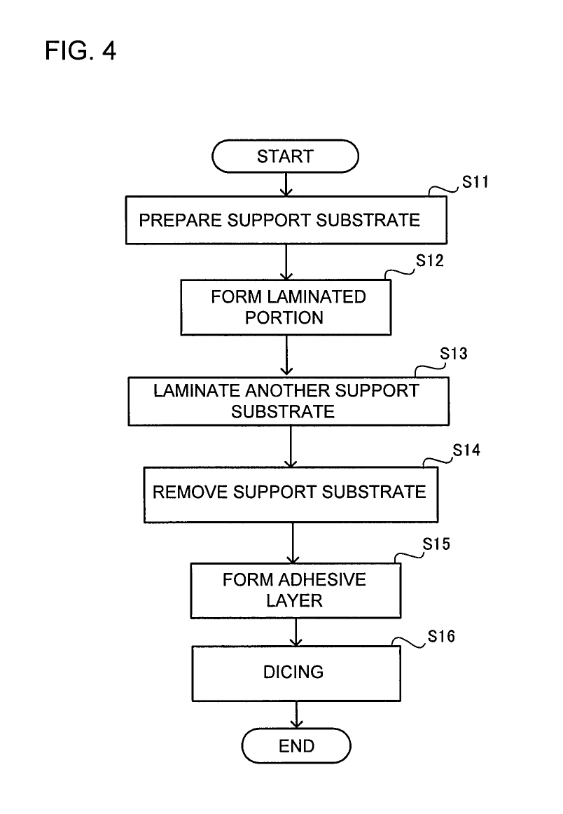

Hereinafter, an example of a manufacturing method of the wiring board 100 according to the present embodiment will be described. A process of manufacturing the wiring board 100 includes a process of manufacturing the wiring structure 10 and a process of manufacturing the main wiring board (multilayer printed board) 200, including a process of mounting the wiring structure 10 on the main wiring board 200. The wiring structure 10 is manufactured through, for example, the process in FIG. 4.

### Process of Manufacturing Wiring Structure 10

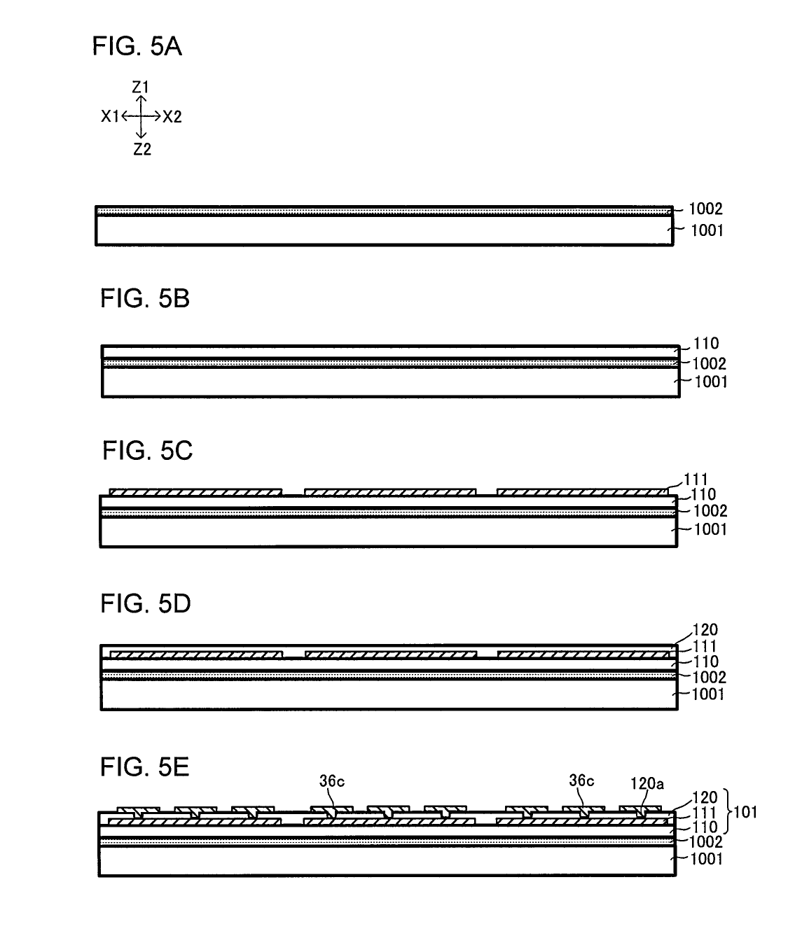

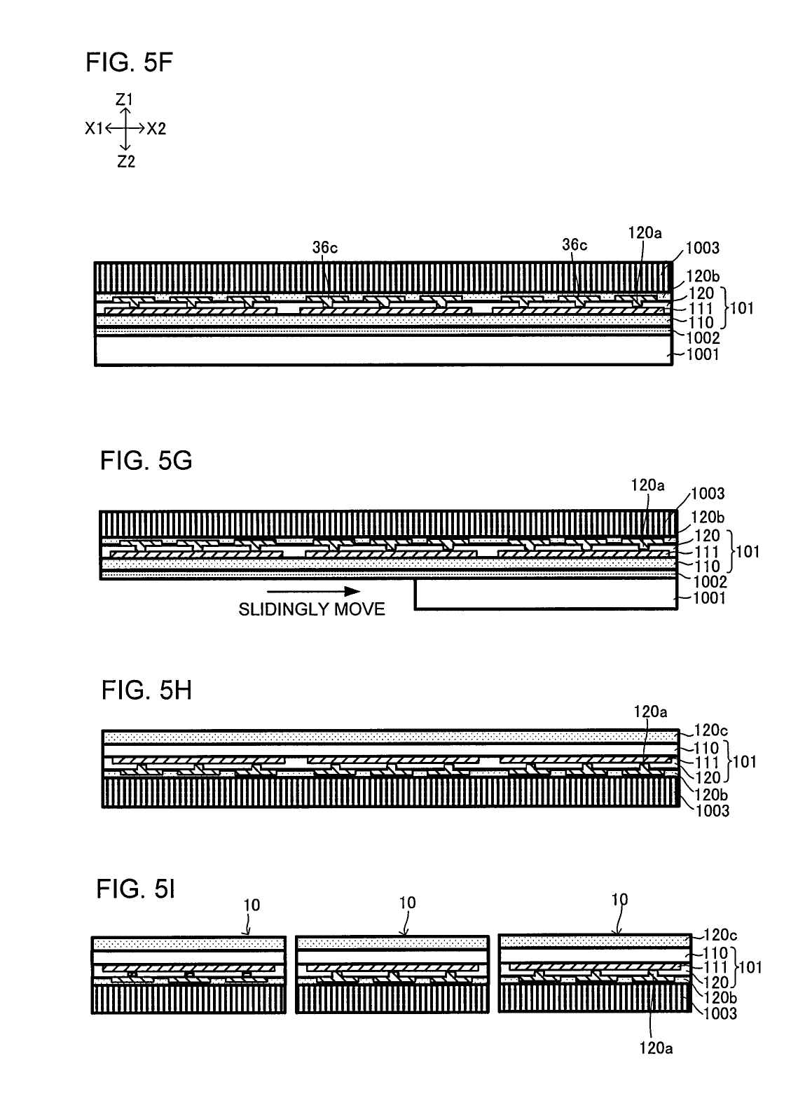

In step (S11) of FIG. 4, as illustrated in FIG. 5A, a support substrate 1001 is prepared. The support substrate 1001 is made of, for example, glass having a flat surface. Then, an adhesive layer 1002 is formed on the support substrate 1001.

In step (S12) of FIG. 4, a laminated portion is formed on the support substrate 1001 by interposing the adhesive layer 1002. The laminated portion is formed by alternately laminating a resin insulation layer and a conductive pattern (conductive layer).

Specifically, as illustrated in FIG. 5B, for example, the insulation layer 110 (resin insulation layer) made of resin is arranged on the adhesive layer 1002. The insulation layer 110 and the adhesive layer 1002 are adhered, for example, through heating.

Subsequently, as illustrated in FIG. 5C, the conductive pattern 111 is formed on the insulation layer 110, for example, by a semi-additive process (SAP) method. The conductive pattern 111 includes first and second conductor film (111a, 111b) (refer to FIG. 3). More specifically, the first conductor film (111a) includes three layers including a TiN-layer (lower layer), a Ti-layer (intermediate layer), and a Cu-layer (upper layer). Since films of these metal layers are made, for example, through sputtering, excellent adhesion between the fine conductive pattern 111 and the substrate (insulation layer 110) is obtained. In addition, the second conductor film (111b) includes an electroless copper plating film on the Cu-layer and an electrolytic plating film on the electroless copper plating film.

The conductive pattern 111 is formed with high wiring density. For example, a line/space (L/S) ratio of the conductive pattern 111 is set at 1/1 μm or higher and 5/5 μm or lower, and preferably, 3/3 μm or higher and 5/5 μm or lower. Here, the “line” refers to a pattern width, and the “space” refers to a distance between the patterns, that is, a distance between the centers of the pattern widths. Here, the wiring density is defined based on a design rule similar to that used when a wiring line is formed in a semiconductor device such as an IC or an LSI.

As illustrated in FIG. 5D, an insulation layer 120 is formed on the insulation layer 110, for example, through a laminating process. The insulation layer 120 is formed to cover the conductive pattern 111.

A hole (via hole) is formed in the insulation layer 120 using, for example, a laser. The hole reaches the conductive pattern 111 and a part thereof is exposed. Here, the diameter of the hole is small. For example, the diameter of the hole is set at 1 μm or larger and 10 μm or smaller, and preferably at 0.5 μm or larger and 5 μm or smaller. Then, as desired, desmearing or soft etching is performed.

A via conductor (120a) (filled conductor) is formed in the hole, for example, by a semi-additive process (SAP), and a conductor pad (36c) connected to the via conductor (120a) is formed on the insulation layer 120.

As a result, as illustrated in FIG. 5E, a laminated portion 101 having the insulation layers 110 and 120 and the conductive pattern 111 is formed on the support substrate 1001. A via conductor (120a) is formed in the insulation layer 120 of the laminated portion 101. The conductor pad (36c) connected to the via conductor (120a) is formed on the insulation layer 120.

In step (S 13) of FIG. 4, as illustrated in FIG. 5F, another support substrate, 1003, is prepared. The support substrate 1003 is made of, for example, glass having a flat surface as in the support substrate 1001. In addition, the support substrate 1003 is laminated on the laminated portion 101 by interposing an adhesive layer (120b).

In step (S14) of FIG. 4, the support substrate 1001 is removed. Specifically, as illustrated in FIG. 5G, after the adhesive layer 1002 is softened by, for example, laser irradiation, the support substrate 1001 slides in an X-direction (or Y-direction) so that the support substrate 1001 is removed from a second main surface of the laminated portion 101. In addition, after the support substrate 1001 is removed from the laminated portion 101, for example, when the adhesive layer 1002 remains on the second main surface of the laminated portion 101, it is cleaned to remove the adhesive layer 1002. Then, as illustrated in FIG. 5H, the laminated portion 101 is formed on the support substrate 1003. Furthermore, the support substrate 1001 may be reused, for example, through cleaning or the like.

In step (S15) of FIG. 4, the adhesive layer (120c) is formed on the laminated portion 101. Specifically, the adhesive layer (120c) is formed on the laminated portion 101, for example, using a laminator such that an adhesive has a uniform thickness.

In step (S16) of FIG. 4, as illustrated in FIG. 5I, the wiring structure 10 is diced by cutting it along predetermined dicing lines, for example, using a dicing saw. In this manner, multiple wiring structures 10 are obtained. In the obtained wiring structure 10, the laminated portion 101 is formed on the support substrate 1003 by interposing the adhesive layer (120b), and the adhesive layer (120c) is further formed on the laminated portion 101.

In the method of manufacturing the wiring structure 10 according to the present embodiment, since a glass plate having a flat surface is used in the support substrates 1001 and 1003, it is suitable for manufacturing the wiring structure 10. In such a manufacturing method, a high-quality wiring structure 10 having a flat surface is obtained while warping is suppressed.

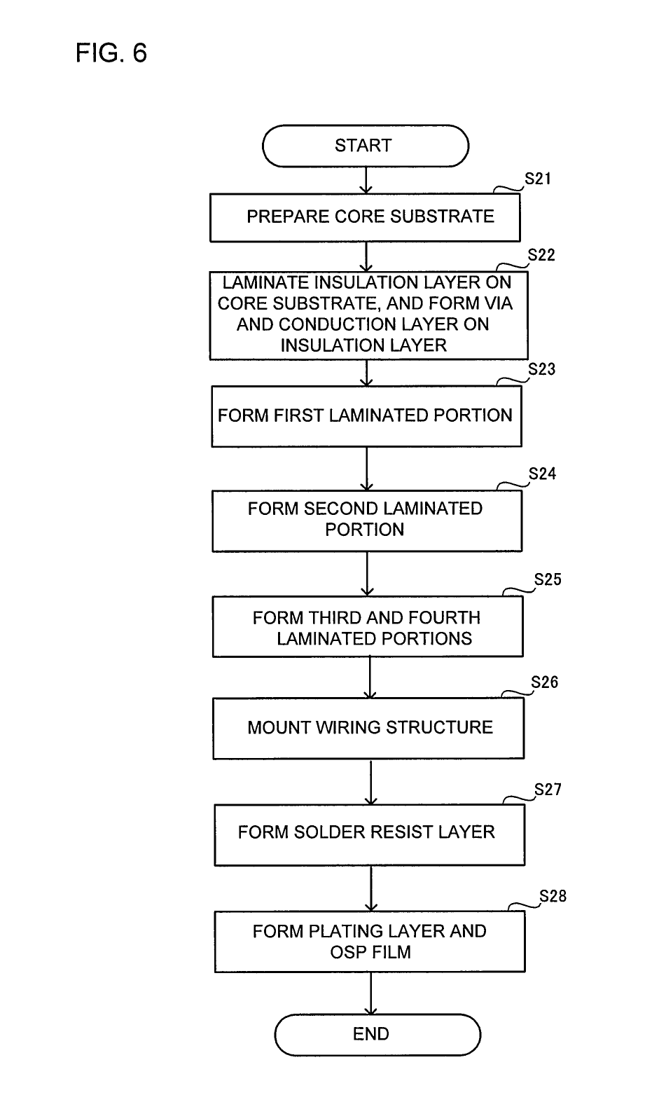

Then, the main wiring board 200 is manufactured, and the wiring board 100 according to the present embodiment is manufactured by mounting the wiring structure 10 on the main wiring board 200. The wiring board 100 may be manufactured, for example, through the process illustrated in FIG. 6.

### Process of Manufacturing Wiring Board 100

First, in step (S21) of FIG. 6, as illustrated in FIG. 7A, the core substrate 20 is prepared by impregnating resin into a reinforcing material. A copper foil (20a) is laminated on a first surface (surface of the first-surface (F1) side of the wiring board 100) and a second surface (surface of the second-surface (F2) of the wiring board 100) of the core substrate 20. A thickness of the core substrate 20 is set at, for example, 0.4 to 0.7 mm. As the reinforcing material, for example, glass cloth, aramid fiber, or glass fiber, may be used. As the resin, for example, an epoxy resin, bismaleimide triazine (BT) resin, or the like may be used. Furthermore, the resin contains particles of hydroxides. For example, hydroxides may include aluminum hydroxide, magnesium hydroxide, calcium hydroxide, barium hydroxide, and the like. Hydroxides are thermally decomposed to generate water. For this reason, it is thought that hydroxides can remove heat from the materials of the core substrate. That is, when the core substrate includes a hydroxide, processing performance by a laser is thought to improve.

Then, the surface of the copper foil (20a) is subjected to treatment with an aqueous solution containing NaOH (10 g/l), NaClO₂ (40 g/l), and Na₃PO₄ (6 g/l), to perform blackening treatment using a blackening bath (oxidation bath).

In step (S22) of FIG. 6, as illustrated in FIG. 7B, a CO₂ laser is irradiated onto the first- and second-surface sides of the core substrate 20 to form the through hole 21 penetrating through the core substrate 20. Specifically, by alternately irradiating the CO₂ laser from the first and second surfaces of the core substrate 20, the through hole 21 is formed when holes formed from the first- and second-surface sides are connected to each other.

The core substrate 20 is immersed in a solution containing permanganate at a predetermined concentration, and desmearing is performed. In this case, a weight-reduction rate of the core substrate 20 is set at 1.0 wt. % or lower, and preferably, 0.5 wt. % or lower. The core substrate 20 is obtained by impregnating resin into a reinforcing material such as glass cloth. When the resin is dissolved through desmearing, the glass cloth protrudes into the through hole. However, if the weight reduction rate of the core substrate 20 is set within such a range, protrusion of the glass cloth is suppressed, and voids are prevented from remaining when the plating is filled in the through hole. Then, a palladium catalyst is applied to the surface of the core substrate 20.

As illustrated in FIG. 7C, the core substrate 20 is immersed in an electroless plating solution so that an electroless plating film 22 is formed on the first and second surfaces of the core substrate 20 and an inner wall of the through hole 21. Materials for forming the electroless plating film 22 may include copper, nickel, and the like. The electrolytic plating film 23a is formed on the electroless plating film 22 using the electroless plating film 22 as a seed layer. The through hole 21 is filled with the electrolytic plating film (23a).

As illustrated in FIG. 7D, an etching resist having a predetermined pattern is formed on the electrolytic plating film (23a) on the substrate surface, and the electroless plating film 22, the electrolytic plating film (23a) and the copper foil are removed from where no etching resist is formed. When the etching resist is removed, the conductive layer (24a) is formed on the first surface of the core substrate 20, and the conductive layer (24b) is formed on the second surface of the core substrate 20. The conductive layers (24a) and (24b) are connected to each other through the electrolytic plating film (23a) (via conductor 23) in the through hole 21.

In step (S23) of FIG. 6, as illustrated in FIG. 7E, the interlayer insulating film (brand name: ABF-45SH, made by Ajinomoto) is laminated on both surfaces (F) and (S) of the core substrate 20 to form the interlayer insulation layers (25a, 25b).

As illustrated in FIG. 7F, using the CO₂ gas laser, the via hole openings (26c, 26d) are respectively formed in the interlayer insulation layers (25a, 25b). In addition, the substrate is immersed in an oxidizing agent such as permanganate, and desmearing is performed.

As illustrated in FIG. 7G, a catalyst such as palladium is applied to surfaces of the interlayer insulation layers (25a, 25b), and the substrate is immersed in an electroless plating solution, so that the electroless plating films (27a, 27b) are formed. Then, a plating resist is formed on the electroless plating films (27a, 27b). In addition, the electrolytic plating films (28a, 28b) are formed on the electroless plating films (27a, 27b) exposed from the plating resist. Then, the plating resist is removed using a solution containing monoethanolamine. The electroless plating film between the electrolytic plating films is removed by etching, so that the conductive layers (29a, 29b) and via conductors (30a, 30b) are formed. Subsequently, surfaces of the conductive layers (29a, 29b) are subjected to Sn-plating to form an SnCu layer. A silane coupling agent is applied onto the SnCu layer.

In step (S24) of FIG. 6, as illustrated in FIGS. 7H and 71, the aforementioned process is repeated. As a result, the interlayer insulation layers (26a, 26b) are laminated on the interlayer insulation layers (25a, 25b) from the first- and second-surface sides of the core substrate 20, and the conductive layers (31a, 31b) and the via conductors (32a) and (32b) are formed on the interlayer insulation layers (26a, 26b) (refer to FIG. 7J).

In step (S25) of FIG. 6, as illustrated in FIG. 7K, the interlayer insulation layers (33a, 33b) are laminated, the interlayer insulation layers (39a, 39b) are further laminated on the interlayer insulation layers (33a, 33b), respectively, and the aforementioned process is repeated. As a result, the interlayer insulation layers (33a, 33b) are laminated on the interlayer insulation layers (26a, 26b), respectively, from the first- and second-surface sides of the core substrate 20, and the conductive layers (35a, 35b) and via conductors (36a, 36b) are formed in the interlayer insulation layers (33a, 33b), respectively. In addition, the interlayer insulation layers (39a, 39b) are laminated on the interlayer insulation layers (33a, 33b), respectively, from the first and second surfaces of the core substrate 20, and the conductive layers (37c, 37d) and the via conductors (38c, 38d) are respectively formed in the interlayer insulation layers (39a, 39b).

Then, in step (S26) of FIG. 6, as illustrated in FIG. 7K, the wiring structure 10 is mounted on a predetermined position of the interlayer insulation layer (39a). Then, the support substrate 1003 is released.

In step (S27) of FIG. 6, as illustrated in FIG. 7L, the solder-resist layers (40a, 40b) are formed on respective sides of the substrate.

Then, as illustrated in FIG. 7M, the opening (40c) is formed such that an upper surface including the conductor pad (36c) (pad formation area (36f)) of the wiring structure 10 is exposed, and the openings (40d, 38b) are formed. The openings (40c, 40d, 38b) are formed, for example, through photolithography. Here, upper surfaces of conductive layers (37c, 37d) (via conductors (38c, 38d)) exposed from the openings (40d, 38b) each serve as a solder pad.

In step (S28) of FIG. 6, as illustrated in FIG. 7N, a nickel plating layer is formed on the solder pad of the conductive layers (37c, 37d), and a gold plating layer is further formed on the nickel plating layer. Alternatively, instead of a nickel-gold layer, a nickel-palladium-gold layer may be formed.

In order to cover the conductor pad (36c) of the upper surface of wiring structure 10, a thin film made of, for example, an element selected from a group of an organic solder preservative (OSP), NiPdAu, NiAu, Sn, is formed. Then, a solder ball is mounted on the opening (38b) and reflow is performed, so that the wiring structure 10 is arranged in a position in which the opening (40c) of the first-surface (upper surface) side is formed, and a solder bump (43b) is formed on the second-surface (rear surface) side. As a result, the wiring board 100 as a multilayer printed wiring board is completed.

Then, in the process of mounting a semiconductor device (semiconductor chip) such as the MPU 50 and the DRAM 51 on the wiring board 100, a space between the wiring board 100, the MPU 50, and the DRAM 51 is filled with the underfill resin 70. As a result, the upper surface of the wiring structure 10 is covered by the underfill resin 70 (refer to FIGS. 1A, 1B, and 3).

The method of manufacturing the wiring board according to the present embodiment is not limited to those described above, but may be variously modified without departing from the spirit and scope of the invention. Hereinafter, modified examples of the present embodiment will be described.

### First Modified Example

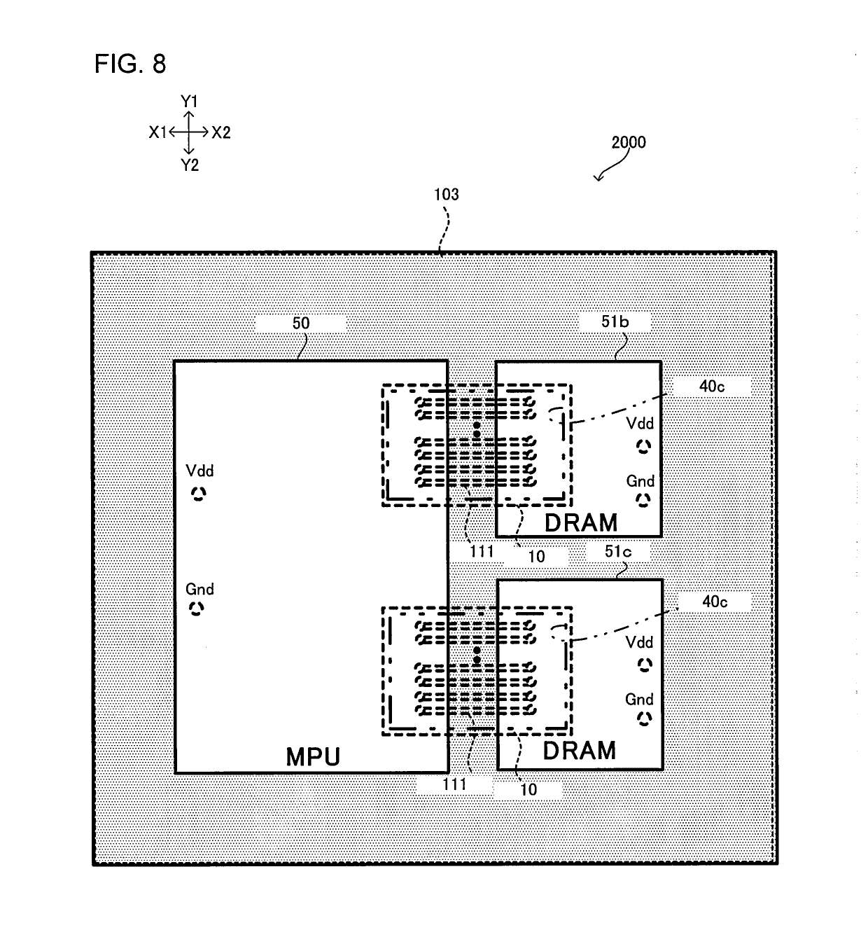

In the embodiment described above, the MPU 50 and the DRAM 51 are connected by a single wiring structure 1. By contrast, in a wiring board 103 of the present modified example, a pair of (or multiple) wiring structures 10 are used to connect the MPU 50 and a pair of DRAMs (51b, 51c) as illustrated in FIG. 8. Since the rest of the structure is the same as that described above, the same reference numerals are used for those corresponding to the elements above, and a description thereof is omitted.

By adopting such a connecting structure, the reliability of electrical connection between the MPU 50 and a pair of DRAMs (51b) and (51c) is improved, compared with cases where only a single wiring structure 10 is used. That is, for example, a dedicated wiring structure 10 may be employed depending on a characteristic of the DRAMs (51b) and (51c) (such as wiring pitch and wiring line width). Therefore, accuracy of the electrical connection is improved. As a result, performance of the DRAMs (51b) and (51c) connected to the MPU 50 is maximized.

### Second Modified Example

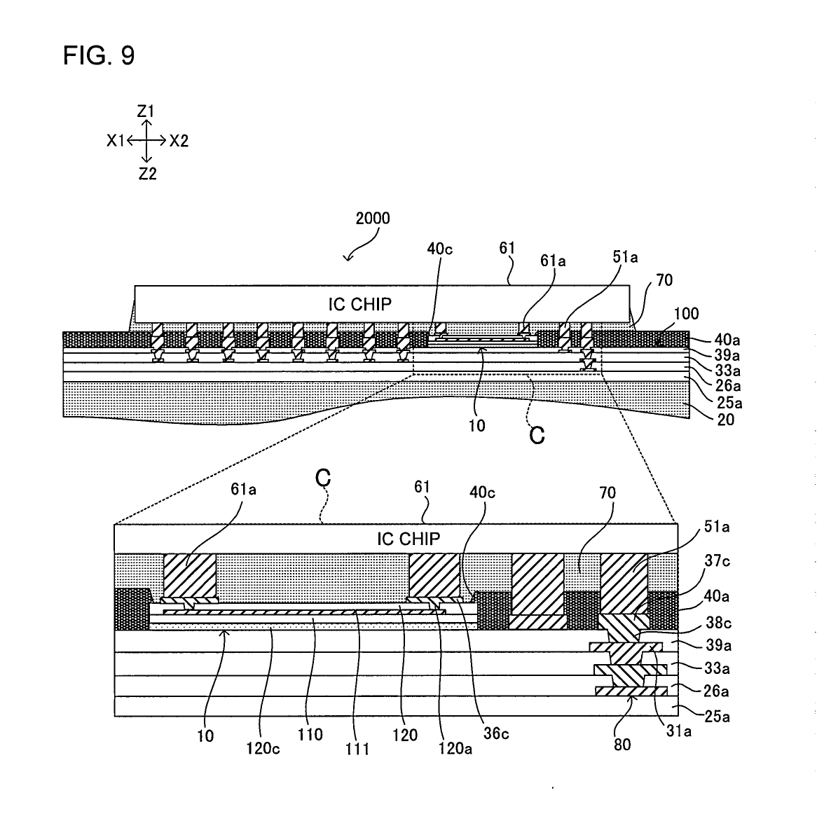

In the first embodiment described above, the conductive pattern 111 of the wiring structure 10 is used for signal transmission between the MPU 50 and the DRAM 51. By contrast, in the present modified example, the conductive pattern 111 of the wiring structure 10 is used for signal transmission in a single IC chip 61 as illustrated in FIG. 9. The rest of the structure and the measurements of each element are the same as those described above in the first embodiment.

### Second Embodiment

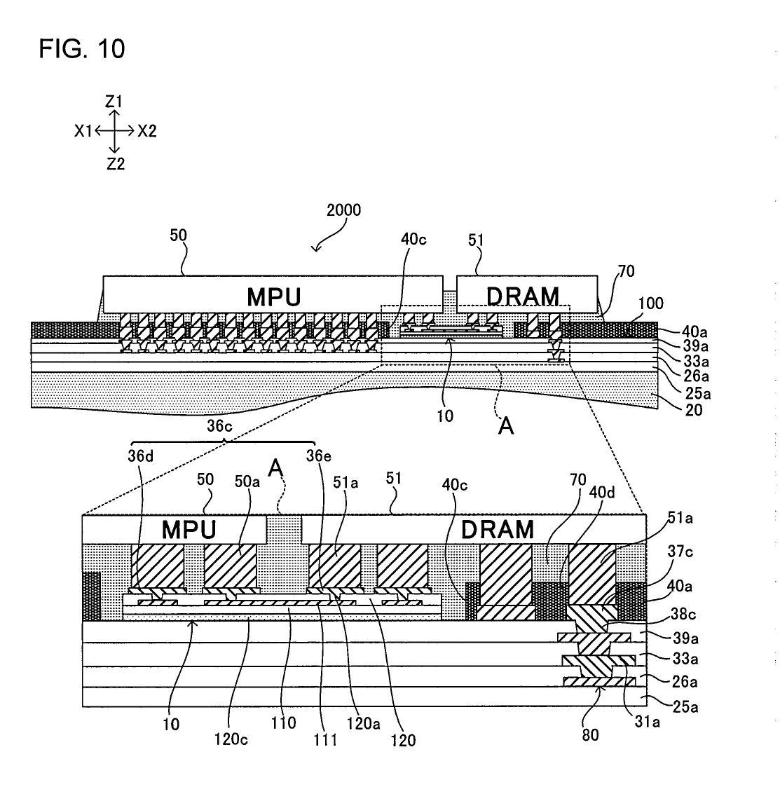

In the first embodiment described above, the periphery (side surface) of the wiring structure 10 is covered by the solder-resist layer (40a), and the wiring structure 10 is arranged on the main wiring board 200 while the upper surface of the wiring structure 10 is covered by the underfill resin 70 (refer to FIGS. 1A, 1B, and 3). By contrast, according to the second embodiment, the entire wiring structure 10 including the periphery is not covered by the solder-resist layer (40a) as illustrated in FIG. 10. Instead, the wiring structure 10 is arranged on the main wiring board 200 while being covered by the underfill resin 70 filled in the opening (40c).

In the uppermost layer of the main wiring board 200 according to the second embodiment, the wiring structure 10 is not covered by the solder-resist layer (40a), but is covered by the underfill resin 70 filled in the opening (40c). As a result, since the wiring structure 10 is not affected by a thermal history of the solder-resist layer (40a) having a different coefficient of thermal expansion (CTE), cracking is prevented in a contact portion between the wiring structure 10 and the solder-resist layer (40a). The rest of the structure and the dimensions of each element are the same as those of the first embodiment. Therefore, the same reference numerals are used for those corresponding to the elements above, and a description thereof is omitted.

The order and the contents of the processes for manufacturing the wiring board according to an embodiment of the present invention are not limited to those in the embodiments and the modified examples described above. Instead, the order and the contents may be modified freely within the scope that does not deviate from the gist of the present invention. Furthermore, some step may be omitted appropriately depending on purposes or the like.

The embodiments and modified examples may be employed in any combination thereof. An appropriate combination may be selected according to usage purposes or the like.

The wiring board according to an embodiment of the present invention can be appropriately applied to a package substrate where multiple semiconductor devices (dies) are mounted. In addition, the method for manufacturing the wiring board according to an embodiment of the present invention may be appropriately applied to a manufacturing of such a package substrate.

When all semiconductor devices to be mounted are concentrated on a wiring layer of the electronic component, that is, all wiring lines of power supply systems and signal systems are concentrated on the high density wiring layer of the electronic component, it is thought that problems may occur in electrical characteristics.

In addition, when high density wiring is formed in an area that includes an electronic component, while only resin is formed in the neighboring area where no electronic component is included, the electronic component is susceptible to the thermal expansion and contraction of the resin. It is thought that cracking is likely to occur in the heat-resistant base material of the wiring board.

In addition, if an electronic component is formed in an insulation layer such as an interlayer insulation layer or a solder-resist layer, a small-diameter via hole is provided to connect the electronic component and the IC chip.

Accordingly, in a structure where an electronic component is embedded in the insulation layer, in the insulation layer a small-sized via hole corresponding to a wiring line having a pitch of 40 to 50 μM is formed. However, it is difficult to form such a via hole using photolithography or laser due to resolution problems.

Moreover, in order to form a via hole through photolithography, a developing solution is used to remove resists not needed for pattern formation. Therefore, the insulation reliability between wiring lines may be degraded due to the developing solution.

In addition, since such an electronic component has a thin thickness of approximately 20 μm, it is likely to be damaged by laser.

According to one aspect of the invention, a wiring board is provided that includes: a first insulation layer; a first conductive pattern formed on the first insulation layer; a wiring structure including a second insulation layer provided on the first insulation layer and a second conductive pattern on the second insulation layer; and a third insulation layer including a first opening provided on the first insulation layer and the first conductive pattern to expose at least a part of a surface of the wiring structure and a second opening that exposes at least a part of the first conductive pattern. In such a wiring board, a third conductive pattern of an outermost layer of the wiring structure has a mounting pad for mounting a semiconductor device, and the first opening exposes a pad formation area of the mounting pad.

According to another aspect of the invention, there is provided a method for manufacturing a wiring board, including: forming a first conductive pattern on a first insulation layer; on the first insulation layer, providing a wiring structure having a second insulation layer and a second conductive pattern on the second insulation layer; on the first insulation layer, providing a third insulation layer, which covers the wiring structure and the first conductive pattern; forming a first opening inside the third insulation layer so that at least a part of a third conductive pattern of a top layer of the wiring structure is exposed; and forming a second opening inside the third insulation layer so that at least a part of the first conductive pattern is exposed. In such a manufacturing method, a wiring board is formed to have the third conductive pattern, which includes a pad formation area for mounting a semiconductor device, and the first opening, which is formed to expose the pad formation area.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
a first insulation layer;
a first conductive pattern structure formed on the first insulation layer;
a wiring structure formed on the first insulation layer and comprising a second insulation layer and a second conductive pattern structure on the second insulation layer; and
a third insulation layer formed on the first insulation layer and the first conductive pattern structure and having a first opening portion and a second opening portion such that the first opening portion is exposing at least a portion of a surface of the wiring structure and the second opening portion is exposing at least a portion of the first conductive pattern structure,
wherein the wiring structure includes a third conductive pattern structure forming an outermost layer of the wiring structure and comprising a mounting pad structure configured to mount a semiconductor device, and the first opening portion is formed such that the first opening portion is exposing a pad formation area of the mounting pad structure.

2. The wiring board according to claim 1, wherein the third insulation layer is a solder-resist layer.

3. The wiring board according to claim 1, wherein the first opening portion of the third insulation layer is formed such that the third insulation layer is covering a peripheral portion of the wiring structure.

4. The wiring board according to claim 1, wherein the second conductive pattern structure has a pattern width which is smaller than a pattern width of the first conductive pattern structure.

5. The wiring board according to claim 1, wherein the second conductive pattern structure has a distance between adjacent patterns which is smaller than a distance between adjacent patterns in the first conductive pattern structure.

6. The wiring board according to claim 1, further comprising an adhesive layer interposed between the first insulation layer and the wiring structure.

7. The wiring board according to claim 1, wherein the first insulation layer has a mounting pad structure configured to mount a first semiconductor device and a second semiconductor device.

8. The wiring board according to claim 7, wherein the mounting pad structure of the first insulation layer includes a first pad structure connected to the first semiconductor device and a second pad structure connected to the second semiconductor device, and the first pad structure comprising a plurality of pads has a distance between the pads which is smaller than a distance between a plurality of pads in the second pad structure.

9. The wiring board according to claim 7, wherein the second conductive pattern structure forms a signal line structure configured to connect the first and second semiconductor devices.

10. The wiring board according to claim 8, wherein the second conductive pattern structure forms a signal line structure configured to connect the first and second semiconductor devices.

11. The wiring board according to claim 1, wherein the second conductive pattern structure has a line/space L/S ratio of patterns which is set in a range of 1/1 μm or higher and 5/5 μm or lower.

12. A method of manufacturing a wiring board, comprising:
forming a first conductive pattern structure on a first insulation layer;
positioning on the first insulation layer a wiring structure comprising a second insulation layer, a second conductive pattern structure on the second insulation layer and a third conductive pattern structure forming an outermost layer of the wiring structure;
forming on the first insulation layer a third insulation layer such that the third insulation layer covers the wiring structure and the first conductive pattern structure;
forming a first opening portion in the third insulation layer such that the first opening portion exposes at least a portion of the third conductive pattern structure of the wiring structure; and
forming a second opening portion in the third insulation layer such that the second opening portion exposes at least a portion of the first conductive pattern structure,
wherein the third conductive pattern structure includes a pad formation area for mounting a semiconductor device, and the forming of the first opening includes exposing the pad formation area of the third conductive pattern structure.

13. The method according to claim 12, wherein the first opening portion is formed such that the third insulation layer covers a periphery portion of the wiring structure.

14. The method according to claim 12, wherein the forming of the third insulation layer comprises forming a solder-resist layer forming the third insulation layer.

15. The method according to claim 12, wherein the first opening portion of the third insulation layer is formed such that the third insulation layer is covering a peripheral portion of the wiring structure.

16. The method according to claim 12, further comprising forming the wiring structure, wherein the second conductive pattern structure is formed such that a pattern width of the second conductive pattern structure is smaller than a pattern width of the first conductive pattern structure.

17. The method according to claim 12, further comprising forming the wiring structure, wherein the second conductive pattern structure is formed such that a distance between adjacent patterns in the second conductive pattern structure is smaller than a distance between adjacent patterns in the first conductive pattern structure.

18. The method according to claim 12, further comprising forming an adhesive layer positioned to adhere the wiring structure to the first insulation layer.

19. The method according to claim 12, further comprising forming on the first insulation layer a mounting pad structure configured to mount a first semiconductor device and a second semiconductor device.

20. The method according to claim 12, further comprising forming the wiring structure, wherein the second conductive pattern structure is formed such that a line/space L/S ratio of patterns in the second conductive pattern structure is set in a range of 1/1 μm or higher and 5/5 μm or lower.
